(19) United States
(12) Patent Application Publication
(10) Pub. No.: US 2025/0158428 A1
(43) Pub. Date: May 15, 2025

(54) METHOD AND CIRCUIT FOR USING SENSEFET FOR BATTERY PROTECTION MODULE

(71) Applicant: Alpha and Omega Semiconductor International LP, Toronto (CA)

(72) Inventors: Sitthipong Angkititrakul, Dublin, CA (US); Jian Yin, San Ramon, CA (US)

(21) Appl. No.: 18/509,168

(22) Filed: Nov. 14, 2023

(51) Int. Cl. H02J 7/00; G01R 31/3842; H01M 10/42; H01M 10/44; H02H 7/18

(52) U.S. Cl. CPC H02J 7/00302; G01R 31/3842; H01M 10/44; H02H 7/18; H02J 7/00714; H01M 2010/4271; H01M 2200/105

(57) ABSTRACT

A device for resistor lossless current sensing includes a first power transistor, a sense transistor and current sense conversion circuit. The first sense transistor has its gate conductively coupled with a gate of the first power transistor and its drain conductively coupled with the drain of the first power transistor. The current sense conversion circuit is configured to convert a current output from the first sense transistor to an output voltage. The current output from the first sense resistor and output voltage are proportional to the current from the current input to the device and the current sense conversion circuit generates the output voltage which is not in a current path through the first power transistor.

### FIELD OF THE DISCLOSURE

Aspects of the present disclosure relate to current sensing particularly; aspects of the present disclosure relate to current sensing for battery protection.

### BACKGROUND OF THE DISCLOSURE

Batteries are increasingly being integrated into modern devices. Part of integration of a battery into a device is controlling the charging and discharging of the battery. Overcharging or a problem with the battery can lead to dangerous conditions such as a fire or explosion.

Thus, battery protection modules are also being integrated into devices to protect against dangerous fault conditions.

FIG. 1 shows an example circuit diagram for a prior art battery protection module. The battery protection module 100 shown here includes a Battery Monitor Integrated Circuit (IC) 101, a sense resistor R1, and power transistors 102, 103 connected in back-to-back configuration. The power transistor 102 is used to control battery charging current, while the power transistor 103 is used to control battery discharging current. Additionally, the battery protection module 100 here also includes a temperature monitoring element in the form of a Negative Temperature Coefficient resistor NTC. Here, the battery BATT is shown as part of the circuit, but it is optional and in some implementations, it may be removable. The battery protection module 100 receives current through current inputs 104 and 105. Passive components R_{VDD}, R2, and R3 are chosen to condition the voltage to be within operational range of the battery monitor IC. As shown here current inputs to the positive terminal 104 charging the battery, while the current inputs to the negative terminal 105 discharging the battery.

The Battery Monitor IC includes inputs for positive voltage V_{DD}, ground or negative supply Voltage V_{SS}, temperature related voltage, Tᵢₙ, Reference voltage V−, and sense voltage R_{SENS}. The Battery Monitor IC in the prior art implementation shown detects current through the device using the sense resistor R1. Outputs D_{OUT} and C_{OUT} output gate signals configured to control Power MOFET 103 and MOSFET 102 respectively. The reference voltage input V− monitors the negative voltage terminal and serves as the voltage reference. R_{SENS} is monitored and the voltage drop between V− and R_{SENS} and the known resistance of R1 are used in Ohm's equation to determine the current passing through the circuit. This current may be used to control the operation of the battery, for example controlling discharge or charging state. In the charging state the Power MOSFET 102 is switched to the “on” state by a voltage applied to the gate allowing current to flow from the positive terminal 104, through the battery, to the negative terminal 105. The Power transistor 103 may switch off preventing the backflow of current or may remain on for a reduced resistance current pathway. In the discharging state the transistor 103 is switched to the “on” state by a sufficient voltage applied to the gate allowing current to flow from the negative terminal 105, through the battery, to the positive terminal 104. The transistor 102 may switch off preventing the backflow of current or may remain on for a reduced resistance current pathway. The difficulty with this monitoring setup is that the resistor R1 is always in the charging and discharging current path. This causes additional power loss in the resistor R1, which dissipates as heat. Thus, the battery protection module has to operate at higher temperature which may have the adverse effects on the battery protection module and the battery.

It is within this context that aspects of the present disclosure arise.

### BRIEF DESCRIPTION OF THE DRAWINGS

The teachings of the present disclosure can be readily understood by considering the following detailed description in conjunction with the accompanying drawings, in which:

FIG. 1 shows an example circuit diagram for a prior art battery protection module.

FIG. 2 depicts an example circuit diagram of a prior art current measurement circuit using a sense transistor.

FIG. 3A is a circuit diagram of the improved power protection module having the power MOSFETs and current sense conversion circuit coupled to the negative voltage input of the power protection circuit according to aspects of the present disclosure.

FIG. 3B depicts an example circuit diagram of an alternative implementation of the improved power protection module having the power MOSFETs and current sense conversion circuit coupled to the positive voltage input of the power protection circuit according to aspects of the present disclosure.

FIG. 4 is a circuit diagram depicting an example improved power protection module having a current sense conversion circuit integrated into the battery protection IC package according to an aspect of the present disclosure.

FIG. 5 is a circuit diagram depicting the power protection module with a detailed view of the current sense conversion circuit according to aspects of the present disclosure.

FIG. 6A is a diagram depicting a lead frame packaging of the power transistors, sense transistors and the current sense circuit according to aspect of the present disclosure.

FIG. 6B is a diagram depicting a back-to-back configuration for power transistors with integrated sense transistors according to aspects of the present disclosure.

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, examples of embodiments of the invention described below are set forth without any loss of generality to, and without imposing limitations upon, the claimed invention.

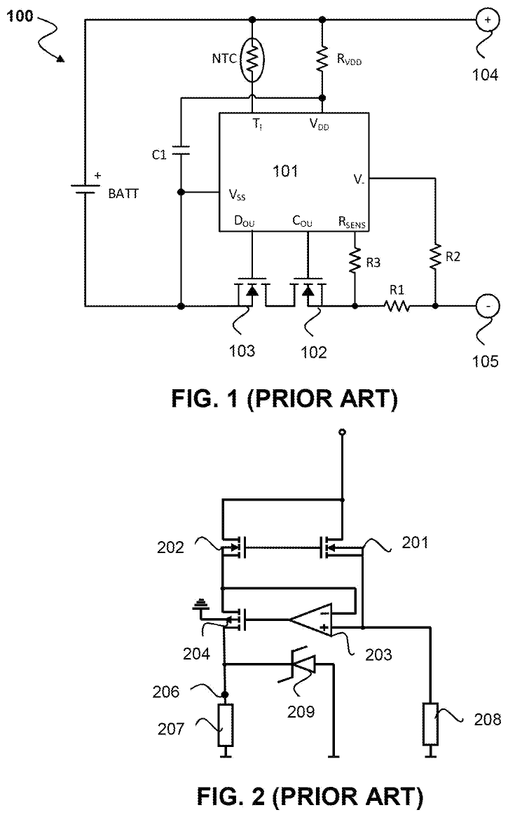

FIG. 2 depicts an example circuit diagram of a prior art current measurement circuit using a sense transistor. Here the power MOSFET 201, corresponding, e.g., to either one of the back-to-back MOSFET 102 or MOSFET 103 in FIG. 1, is a large collection of small transistor elements. Typically, the Power MOSFET has on the order of 1000 s or 10000 s of individual transistor elements connected in parallel to form the Power MOSFET 201. The sense FET 202 includes many times fewer transistor elements than the Power MOSFET 201. Typically, the Sense FET 202 includes on the order of 10 s or 100 s of transistor elements connected in parallel. The gates of the Power MOSFET 201 and the Sense FET 202 are conductively coupled to each other. Likewise their drains are conductively coupled together. An aspect of this is that the ratio of the number of active transistor elements of the power MOSFET to the number of active transistor elements of the Sense FET 202 is known. This ratio can be used to determine the scaling of current passing through the Sense FET 202 as compared to the Power MOSFET 201.

During operation, the gate of the power MOSFET 201 is energized allowing current to flow through to load 208. The gate of the Sense FET 202 is also energized to allow current to flow through PMOS 204 and resistor 207. The amplifier 203 adjusts the gate voltage of the PMOS 204 such that the voltage at the source of the Sense FET 202 to be the same voltage as the voltage at the source of the Power MOSFET 201. The current is then measured across sense resistor 207 at measurement node 206. The Zener diode 209 here provides a shunt to ground for clamping to the voltage at node 206.

Aspects of the present disclosure utilize a Sense Transistor with a current sense conversion circuit to generate an output voltage that is equivalent to voltage measured through a sense resistor such as element 207 of FIG. 2. This allows the improved power protection module to use currently available battery monitor ICs that are configured to use sense resistors for current sensing without modification while providing reduced power dissipation due to the lower current amplitude from Sense FET.

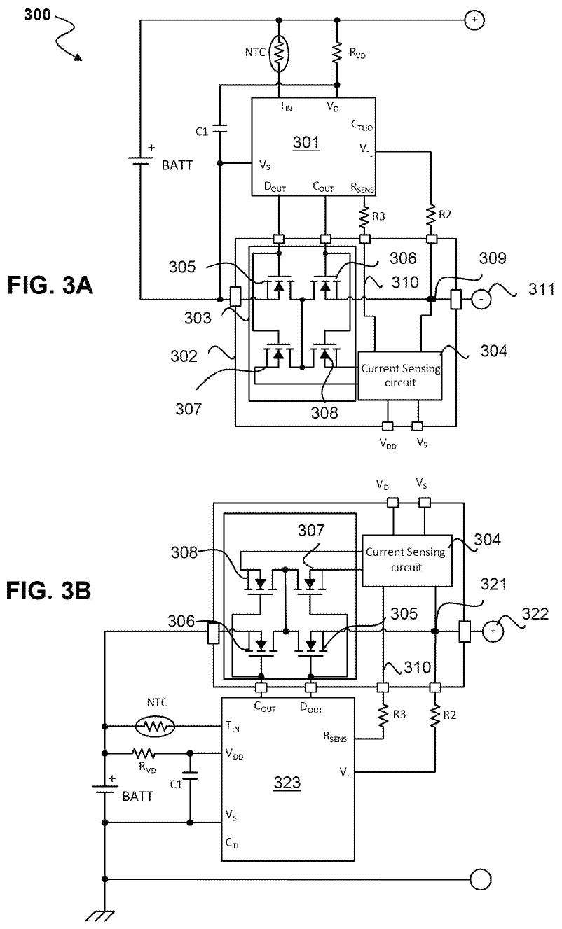

FIG. 3A is a circuit diagram of the improved power protection module using back-to-back MOSFETs with sense transistors according to aspects of the present disclosure. As shown, the improved power protection module according to aspects of the present disclosure may include a Battery Monitor IC 301 and Transistor Current Sense Package 302. The transistor current sense package include back-to-back power transistors 305, 306, one or more corresponding sense transistors 307, 308 and a current sense conversion circuit 304. Alternatively, one or more Power Transistors 305, 306 and corresponding sense transistors 307, 308 may be packaged separately in a Power Transistor package 303 with a discrete current sense conversion circuit 304.

The improved power protection module shown includes two power transistors shown here as N-channel Enhancement mode MOSFETs. It should be noted that P-channel Enhancement mode MOSFETs could be used here with proper configuration of the battery monitor IC. In this implementation each power transistor has a corresponding sense transistor. Here, the first sense transistor 307 is matched with the first power transistor 305 and the second sense transistor 308 is matched with the second power transistor 306. The gate of each sense transistor is conductively coupled to the gate of its corresponding power transistor. Similarly, the drains of the sense transistors and power transistors are conductively coupled to each other. As discussed above, the sense transistor has fewer transistor elements than the power transistor and the ratio of the number of transistor elements in the power transistor to the number of transistor elements in the sense transistor may be used to determine proportion of the current that will pass through the sense transistor.

As used herein, “conductively coupled” means that the described component, circuit, or part of a circuit is receiving electrical energy from the component, circuit, or part of a circuit to which it is coupled. The electrical energy may be received via a conductive trace, conductive wires, or other conductive components. In contrast inductive coupling means that the described component circuit, or part of a circuit is energized by a magnetic or electric field generated by the component circuit, or part of a circuit to which it is coupled. If two devices or parts of a device are connected it means that the devices receive electrical energy directly by means of a conducting path, through a resistor, or another passive component. The transistor devices discussed herein may be Metal Oxide Field Effect Transistors (MOSFET)s generally but may also encompass other transistor devices such as integrated gate bipolar transistors (IGBT)s, Bipolar Junction Transistors (BJT)s etc. Additionally, while diagrams here show a connection to a Battery, Batt, aspects of the present disclosure are not so limited for example the Battery connection may be a terminal with positive and negative connection points for the battery.

As shown the first sense transistor 307 is connected to a first input of the current sense conversion circuit 304. Here the current output of the first sense transistor 307 is the source of the sense MOSFET. Similarly, the current output of the second sense transistor 308 is connected to a second input of the current sense conversion circuit 304. The current sense conversion circuit 304 generates an output voltage referenced to the negative input voltage 311. In the implementation shown, the reference voltage 309 is from the negative input. The battery protection IC uses the voltage at V− pin as a reference for sensing the current. The V-pin is coupled to node 309 through the resistor R2. In the discharge mode the current conversion circuit 304 is configured to convert a current output from the first sense transistor to an output voltage equivalent to a voltage from the current input to the device 311 measured across a known resistance (e.g., the sense resistor R1 of FIG. 1). Similarly in the charging mode the current conversion circuit 304 is configured to convert a current output from the second sense transistor to an output voltage equivalent to a voltage from the current input to the device 311 measured across a known resistance. The output voltage may be produced on an output voltage line 310 that is connected to the R_{SENS} input of the Battery Monitor IC 301. Thus, the current conversion circuit 304 is configured to replicate the operation of the sense resistor R1 of FIG. 1. The voltage between R_{SENS} and V−, which is generated by the current sense conversion circuit 304, is no longer in the charging or discharging current paths. As the results, it can reduce power loss in the battery protection module, compared to the prior art. FIG. 3B depicts an example circuit diagram in an alternative implementation of the improved power protection module having the power MOSFETs and current sense conversion circuit coupled to the positive voltage input of the power protection circuit according to aspects of the present disclosure. As shown, this power protection module is similar to the one shown in FIG. 3A. Here, the battery protection IC 323 generates an output signal referenced to the positive input V₊ instead of the negative reference voltage input shown in FIG. 3A. The power transistors 305, 306 are connected to the current input 322 to the device, which is the positive voltage rail. Similarly, the current sensing conversion circuit 304 generates the output voltage referenced to the voltage at node 321 to the positive input 322, and to the V₊ input of the battery monitor IC 323. With these modifications normal operation of the power protection module with power transistors and current sense conversion circuit connected to the positive voltage input is accomplished.

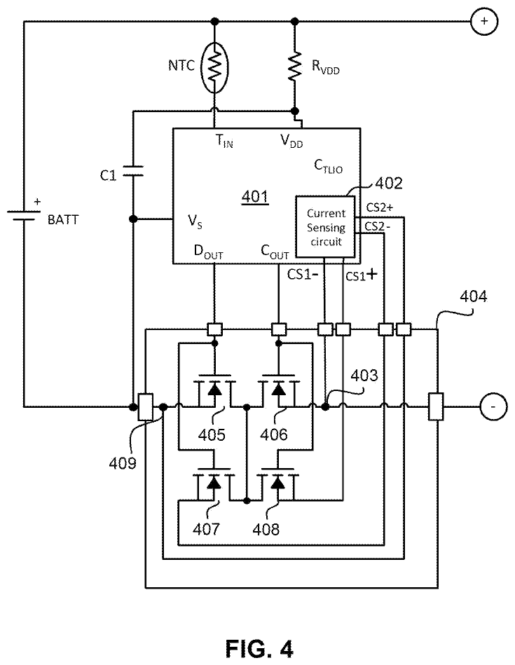

FIG. 4 is a circuit diagram depicting an example improved power protection module having the current sense conversion circuit integrated into the battery protection IC package according to an aspect of the present disclosure. The Battery Monitor IC 401 includes an integrated current sense conversion circuit 402. As such the Battery Monitor IC 401 includes corresponding inputs for the current sense conversion portion CS1−, CS1+, CS2− and CS2+. Inputs CS1− and CS1+ corresponds to current sense conversion input CS+ for the power transistor 406 matched with the sense transistor 408, which provides charging current information. Similarly, the sense transistor 407 is connected to the sense transistor input CS2− and the voltage reference input CS2+ is connected to the source side 409 of the power transistor 405. The inputs CS2+ and CS2− provides the discharging current information. In the configuration shown in FIG. 4, the transistor package 404 includes the power transistors 405, 406, and corresponding sense transistors 407, 408 with additional output lines connected to the node 403 and node 409 for kelvin sensing to the sources of the power transistor 406 and transistor 405, respectively. In an alternative implementation this arrangement may be configured to have the transistor package 404 connected to the positive input by simply changing the positive and negative inputs for CS1 and CS2.

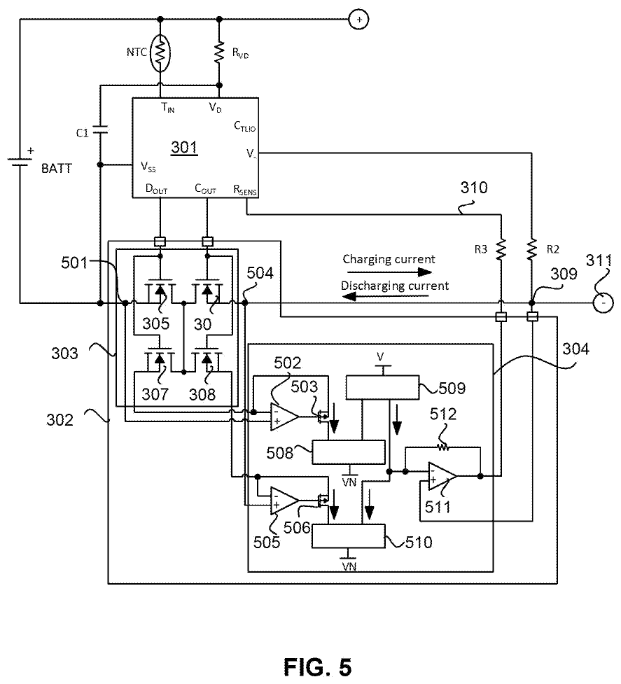

FIG. 5 is a circuit diagram depicting the power protection module with a detailed view of the current sense conversion circuit according to aspects of the present disclosure. This diagram is similar to the diagram of FIG. 3A but as shown discrete circuitry is shown for the current conversion circuit 304. The current conversion circuit is connected via a node 501 to the source side of the power transistor 305 as a reference voltage. The current conversion circuit 304 is also connected via a node 504 to the source side of the power transistor 306 as a reference voltage. The source side of the sense transistor 307 is connected to a transistor input for the current conversion circuit. Similarly, the source side of the sense transistor 308 is connected to a transistor input for the current sense conversions circuit.

As shown, in the current sense conversion circuit 304 the reference input node 501 is connected to the non-inverting input of the operational amplifier 502, the transistor input is connected to the inverting input of the operational amplifier 502. In parallel the transistor input is also connected to the source a P-channel Enhancement mode MOSFET 503. The gate of the PMOS 503 is conductively coupled with the output of the operational amplifier 502. The operational amplifier provides a feedback loop to match the voltage of the source of the sense FET 307 to the voltage of the source of the power transistor 305 to get accurate discharging current information.

Similarly, the reference input is connected via a node 504 to the non-inverting input of the operational amplifier 505, and the transistor input is connected to the inverting input of the operational amplifier 505. In parallel the transistor input is also connected to the source of the P-channel Enhancement mode MOSFET 506. The gate of the PMOS 506 is conductively coupled with the output of the operational amplifier 505. The operational amplifier 505 provides a feedback loop to match the voltage of the source of the sense FET 308 to the voltage of the source of the power transistor 306 to get accurate charging current information.

Turning back to the layout and operation of discharging current sense, a first low side current mirror 508 is connected to the drain of the PMOS 503. The first low side current mirror 508 replicates the current signal from the sense FET 307. The first low side current mirror 508 may be trimmed to condition the current information to better match the ideal scaling factor and compensate for error or variance between the ratio of transistor components in the power transistor 305 and the sense transistor 307. The first low side current mirror also connected to the negative voltage input VN. The high side current mirror 509 is connected to the output of the low side current mirror 508. The high side current mirror 509 is connected to the positive voltage input VP. The output of the high side current mirror 509, which is a replica of the sense FET current, is fed into the transimpedance amplifier 511. The high side current mirror 509 changes the direction of the current so that the current goes into resistor 512. As used herein and as generally understood by those skilled in the art, a current mirror is a circuit designed to copy a current through one active device by controlling the current in another active device of a circuit, keeping the output current constant regardless of loading.

The charging current path includes a single low side current mirror 510. The low side current mirror 510 is conductively coupled to the drain of the PMOS 506 and is configured to replicate the current signal from the sense FET 308. The current mirror 510 may be trimmed to condition the current information to better match the ideal scaling factor and compensate for error or variance between the ratio of transistor components in the power transistor 306 and the sense transistor 308. The current mirror 510 is also connected to the negative voltage input VN. The output of the current mirror 510, which is a replica of the sense FET current, is also fed into the inverting input of the transimpedance amplifier 511. As shown the output of the current mirror 509, which represents the discharging current, is connected together with the output of the current mirror 510, which represents the charging current, and both are input into the inverting input of the output operation amplifier.

A feedback resistor 512 is connected to the output of the current mirror 509 and current mirror 510 across the output operational amplifier 511 to the output of the operational amplifier. Thus, the output operational amplifier 511 is configured to be in the transimpedance amplifier configuration. The transimpedance amplifier configuration here converts the current from inputs to a related voltage output which may be used by the battery monitor IC. The feedback resistor 512 may have a resistance chosen such that the output voltage at R_{SENS} is equivalent to a voltage output of a sense resistor at the current level from the current input measured at node 309 from the current input 311 to the device, which is the negative voltage rail. Additionally, the resistance of the feedback resistor 512 may be chosen to compensate for variations in mismatch between the sense resistors and the power resistors. For example, and without limitation there is some production error tolerance in the ratio of the number of transistor components in the power transistor to the number of transistor elements in the sense transistor, the tolerances may lead to a ratio less or greater than the target ratio of 10,000:1 and the resistance of the feedback resistor may be chosen to compensate for this tolerance. In some implementations the feedback 512 may be a rheostat or other variable resistor which may be tuned to produce the correct output.

Thus, the current sense conversion circuit produces an output voltage that is proportional to the current that passes through the device 311 and generates the output voltage. The output voltage from the current sense conversion circuit is not in the current pathway, which means that implementations of power protection modules according to aspects of the present disclosure may draw less power during operation and may extend the life of connected batteries as compared to prior art implementations which implement a sense resistor.

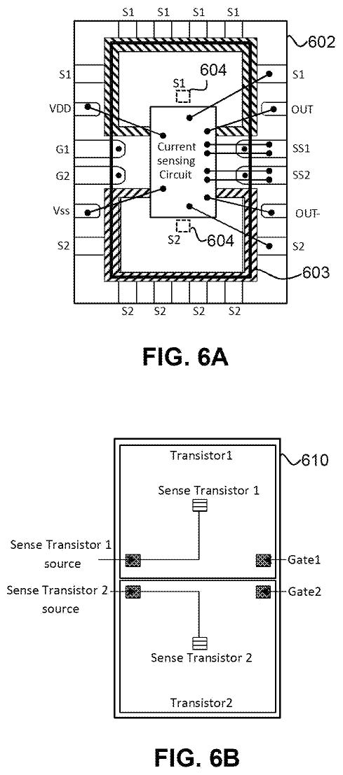

FIG. 6A is a diagram depicting a lead frame packaging of the power transistors, sense transistors and the current sense circuit according to an aspect of the present disclosure. As shown the current sense circuit is mounted in a flip chip configuration with the Power transistors S1 and S2. The sense transistors 604 in this implementation are integrated into the power transistors. The gates of sense transistors 604 are connected to their corresponding gate input G1 or G2 through the redistribution layer 603 (shown clear to provide additional detail). Additionally, the gates of the corresponding power transistors S1 or S2 are also connected to their corresponding gate input at the lead frame G1 or G2. (e.g., S1 is connected to G1 etc.). The sources of each of the sense transistors 604 are connected through the redistribution layer 603 to their corresponding source sense terminal SS1, SS2 of the lead frame 602. Bond wires attach other inputs to the current sense conversion circuit. These inputs include a Positive power supply voltage VDD, Negative power supply voltage Vss, Power transistor S1's source kelvin sense S1, power transistor S2's source kelvin sense S2 and Sense Transistors' sources SS1 and SS2. The outputs of the current sense conversion circuits include sense output OUT+, Negative sense output OUT−.

FIG. 6B is a diagram depicting a back-to-back configuration for power transistors with integrated sense transistors according to aspects of the present disclosure. Here, two transistor devices labeled Transistor 1 and Transistor 2 are mounted together with a common drain plane 610. In some implementations Transistor 1 and Transistor 2 may be mounted in a vertically stacked configuration, back-to-back with a common drain in the middle. The transistor devices include integrated Sense Transistors which have separate source outputs on the package. The gate input of the sense transistor is tied to the gate input of the corresponding power transistor. This creates a dual transistor and sense transistor package that may be used with a current conversion circuit.

While the above is a complete description of the preferred embodiment of the present invention, it is possible to use various alternatives, modifications, and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A device for resistor lossless current sensing comprising:
a first power transistor, wherein a drain of the first power transistor is conductively coupled to a current input to the device;
a first sense transistor, wherein the gate of the sense transistor is conductively coupled with a gate of the first power transistor and a drain of the sense transistor is conductively coupled with the drain of the first power transistor;
a current sense conversion circuit configured to convert a current output from the first sense transistor to an output voltage wherein the current output from the first sense resistor and output voltage are proportional to the current from the current input to the device and wherein the current sense conversion circuit generates the output voltage which is not in a current path through the first power transistor.

2. The device of claim 1 further comprising a second power transistor and a second sense transistor wherein the gate of the second sense transistor is conductively coupled to the gate of the second power transistor and wherein the first power transistor is configured to block current from discharging to the current input to the device when in the off state and the second power transistor is configured to block power from charging from the current input to the device when in the off state.

3. The device of claim 2 wherein the current sense conversion circuit is further configured to convert a current output from the second sense transistor to the output voltage for the charging current information.

4. The device of claim 3 wherein the current sense conversion circuit includes one or more current mirrors for the current output from the first sense transistor and the second sense transistor.

5. The device of claim 4 wherein the current sense conversion circuit includes a resistor and an amplifier arranged in a transimpedance amplifier configuration wherein the current source is conductively coupled to a non-inverting input of the amplifier and an output of at least one of the one or more current mirrors is conductively coupled to the inverting output of the amplifier.

6. The device of claim 1 wherein the current sense conversion circuit includes one or more current mirrors for the current output from the first sense transistor.

7. The device of claim 6 wherein the current sense conversion circuit includes a feedback resistor and an amplifier arranged in a transimpedance amplifier configuration wherein the current source is conductively coupled to a non-inverting input of the amplifier and an output of at least one of the one or more current mirrors is conductively coupled to the inverting output of the amplifier.

8. The device of claim 7 wherein the resistance of the feedback resistor includes a configurable resistance to scale the gain of output voltage amplitude to the current.

9. The device of claim 1 further comprising a battery protection integrated circuit wherein the battery protection integrated circuit is configured to receive the output voltage and control the gate of the first power transistor based at least on the output voltage.

10. The device of claim 9 wherein the current sense conversion circuit is integrated into the battery protection circuit and wherein the battery protection circuit receives the current output from the first sense transistor and a sense input coupled to a source side of the power transistor.

11. The device of claim 1 wherein the first sense transistor is integrated into a component package of the first power transistor.

12. The device of claim 11 wherein the current sense conversion circuit is integrated into the component package of the first power transistor.

13. The device of claim 12 wherein the current sense conversion circuit is vertically stacked over the first sense transistor and first power transistor.

14. The device of claim 13 wherein the component package of the first power transistor includes a lead frame and bond wires connect the current sent conversion circuit to the lead frame.

15. The device of claim 11 further comprising a second power transistor and second sense transistor integrated into the component package of the first power transistor.

16. The device of claim 1 further comprising a battery conductively coupled to the current to the source of the first power transistor.

17. The device of claim 1 wherein the first power transistor includes a plurality of transistor components, and the first sense transistor includes less transistors components than the first power transistor.
